(19) United States
(12) Patent Application Publication
(10) Pub. No.: US 2015/0179477 A1
(43) Pub. Date: Jun. 25, 2015

(54) PACKAGED IC DEVICES AND ASSOCIATED IC DEVICE PACKAGING METHODS

(71) Applicant: STMicroelectronics, Inc., Calamba (PH)

(72) Inventors: AARON CADAG, CALAMBA (PH); BERNIE CHRISANTO ANG, STO. TOMAS (PH)

(73) Assignee: STMicroelectronics, Inc., Calamba (PH)

(21) Appl. No.: 14/138,688

(22) Filed: Dec. 23, 2013

(51) Int. Cl. H01L 21/56; H01L 23/29

(52) U.S. Cl. CPC H01L 21/561; H01L 23/295

(57) ABSTRACT

A method of making packaged integrated circuit (IC) devices includes mixing a waste thermoset polymer material with a thermosetting polymer to form a mixed thermosetting polymer and packaging IC devices in a molding operation using the mixed thermosetting polymer to thereby recycle the waste thermoset polymer material. A packaged IC device includes an IC device and an encapsulating material surrounding the IC device. The encapsulating material includes a thermoset polymer matrix and thermoset polymer particles dispersed in thermoset polymer matrix.

### FIELD OF THE INVENTION

The invention relates to the field of IC devices, and, more particularly, to IC devices packaged in thermoset polymer.

### BACKGROUND

“Thermosetting” polymers exist in a semisolid or viscous state that changes irreversibly into an insoluble three-dimensional polymer network through a process called curing. A cured thermosetting polymer is called a “thermoset” polymer.

Integrated circuit (“IC”) devices are often packaged in thermoset polymers to protect the fragile semiconductor chip. This form of IC packaging typically involves curing a thermosetting polymer about the IC device using a molding process. Two common molding processes used in IC packaging are transfer molding and compression molding.

Unfortunately some molding processes used to package IC devices produce a large amount of thermoset polymer waste material. Because the thermoset polymer waste may be considered to be detrimental to the environment, it is typically disposed of according to applicable regulations. Disposing of the thermoset polymer waste is relatively expensive and time consuming.

### SUMMARY

The problems associated with disposing of thermoset polymer in an IC device packaging process are addressed in one aspect by recycling the waste thermoset polymer. This is achieved by packaging IC devices using waste thermoset polymer in the packaging material. Doing so may reduce the disposal cost and environmental impact associated with the waste thermoset polymers.

A method of making packaged IC devices that addresses these problems includes mixing a waste thermoset polymer material with a thermosetting polymer to form a mixed thermosetting polymer. This mixed thermosetting polymer is used to package a plurality of IC devices in a molding operation by using the mixed thermosetting polymer as a vehicle for recycling the waste thermoset polymer material.

The waste thermoset polymer material may be generated from a waste thermoset polymer producing molding operation, such as, for example, transfer molding. The molding operation used to package the IC device, such as compression molding, does not produce waste thermoset polymer material.

The waste thermoset polymer material in the mixed thermosetting polymer may be processed to form particles within a desire size range, such as 50-200 microns. The mixed thermosetting polymer can contain less than 20% by weight of the waste thermoset polymer material, for example.

This method may be particularly advantageous when waste from a first molding operation that generates waste thermoset polymer is used in the mixed thermosetting polymer to package IC devices in a second molding operation that is different from the first molding operation.

A packaged IC device that may be made according to this method includes an IC device and an encapsulating material surrounding the IC device. The encapsulating material may comprise a thermoset polymer matrix and a plurality of thermoset polymer particles dispersed therein.

### BRIEF DESCRIPTION OF THE DRAWINGS

FIG. 1 is a flowchart illustrating a first method aspect;

FIG. 2 is a flowchart illustrating a second method aspect;

FIG. 3 is a flowchart illustrating a third method aspect; and

FIG. 4 is a cross-section of an exemplary packaged IC device, according to a device aspect.

### DETAILED DESCRIPTION OF THE EMBODIMENTS

In the Summary and in the Detailed Description of The Embodiments, reference is made to particular features, including method steps. Where a particular feature is disclosed in the context of a particular aspect or embodiment, that feature can also be used, to the extent possible, in combination with and/or in the context of other aspects and embodiments.

In this section, embodiments will be described more fully. These embodiments may, however, take many different forms and should not be construed as limited to those set forth herein. Thermoset polymers, including thermoset plastics or resins, contain polymer molecules that cross-link when cured to form a three-dimensional polymeric structure that is very stable. Examples of thermosetting polymers include epoxy resins, phenolic resins, polyurethane resins, melamine resins, urea resins, unsaturated polyester resins, silicone resins, xylene resins, firan resins, melamine phenol resins, polybutadiene resins and the like.

These polymer molecules are cross-linked using a polymer cross-linker compound, often referred to as a hardener. Once the thermosetting polymer is cross-linked and thereby cured, it cannot be reconstituted by melting it or dissolving it in a solvent. This is one of the main reasons that thermoset polymers are typically thrown away rather than reprocessed and reused.

In the semiconductor industry, the thermoset polymer is generally supplied to the mold used to package IC devices in the form of a mold compound that contains the thermosetting polymer and cross-linker compound in a single product.

One of the conventional IC packaging techniques that produces a substantial amount of waste thermoset polymer is called transfer molding. In transfer molding, a pellet of mold compound containing thermosetting polymer is placed into a pot. The pellet is typically a monolithic piece of material that contains substantially more thermosetting polymer than is actually needed to package an IC device in the mold cavity.

The pot is heated to melt the pellet. The heating temperature depends on the properties of the thermosetting polymer and cross-linker in the mold compound. For many of the conventional and commercially available mold compounds, a suitable heating range is between about 160 to about 190 degrees Celsius.

The melted mold compound, including the melted thermosetting polymer, is transferred to the mold cavity, which contains the IC device to be packaged. This is typically accomplished by using a plunger to press the melted material through runners, which are conduits between the pot and cavity.

The melted mold compound fills the cavity and encapsulates the IC device. Some of the melted mold compound remains in the runners or seeps out of the cavity to form culls.

The melted mold compound is then allowed to cure to form a thermoset polymer material about the IC device, making a hardened and durable protective cover thereon. When cured, the thermoset polymer encapsulated IC device is removed from the mold cavity with a substantial amount of excess thermoset polymer attached.

The excess thermoset polymer is typically removed from the packaged device and discarded as waste thermoset polymer material via a process called “deculling.” Deculling involves cutting off the waste thermoset polymer material such as the culls and material left in the runners. Quite often, 40-60% of the weight of the mold compound is wasted. It is typical for an IC packaging entity to generate multiple tons of thermoset polymer waste per month, which is often incinerated by heating to more than 450 degrees Celsius.

Compression molding, another conventional IC packaging technique, produces little, if any, waste thermoset polymer material. One reason for this is that the mold compound used in compression molding is granular, which allows a worker to precisely measure the amount of mold compound needed to match the size of the compression mold cavity.

During compression molding, the measured amount of the granular mold compound is placed into the compression mold cavity and heated. This melts the mold compound, causing it mimic the shape of the compression mold cavity when pressure is applied thereto. The melted thermosetting polymer encapsulates the IC device in the cavity and is allowed to cure. The packaged IC device is then removed from the cavity. Because compression molding produces little, if any, waste thermoset polymer material, deculling is typically not necessary.

Transfer molding and compression molding are but two examples of molding process for which the methods described herein are useful. The method aspects described below, take advantage of the concept that waste thermoset polymer material from a first IC molding operation can be reused in a second molding operation. For example, the waste thermoset polymer material generated while transfer molding a first IC device can be recycled by incorporating it into the mold compound used to compression mold a second IC device.

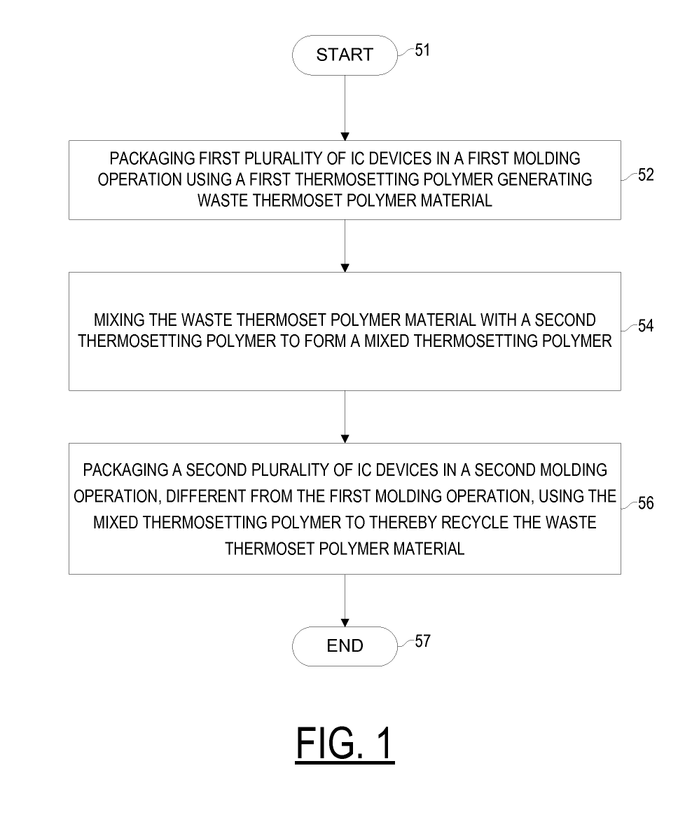

A method of making packaged IC devices, according to a first method aspect, is now described with reference to FIG. 1. In this method, waste thermoset polymer material from a first IC package molding operation is recycled by mixing it with a second thermosetting polymer used in a second IC package molding operation.

Referring now to the flowchart of FIG. 1, the method after the start (Block 51) includes packaging a first plurality of IC devices in a first molding operation using a first thermosetting polymer generating waste thermoset polymer material (Block 52). Thereafter, the method includes mixing the waste thermoset polymer material with a second thermosetting polymer to form a mixed thermosetting polymer (Block 54), and packaging a second plurality of IC devices in a second molding operation, different from the first molding operation, using the mixed thermosetting polymer to thereby recycle the waste thermoset polymer material (Block 56), before ending at Block 57.

The first molding operation is a molding operation that produces thermoset polymer waste material when used to package IC devices. One possible example of the first molding operation is the transfer molding process previously described because it produces waste that would otherwise be discarded. Another example of the first molding operation is a compression molding process that produces waste thermoset polymer material, which might occur during pre-production runs, test runs, or quality control runs.

In certain cases, the waste thermoset polymer material generated by the first molding operation may be greater than 30% by weight of the first thermosetting polymer.

The first thermosetting polymer generating waste thermoset polymer material may be a thermosetting polymer that cures to form a thermoset polymer and is used in a molding operation that produces waste thermoset polymer material. The identity of the first thermosetting polymer depends on the desired properties of the thermoset polymer that packages the IC device in the first molding operation. There are many commercially available mold compounds containing thermosetting polymers that that those skilled in the art may select for use as the first thermosetting polymer.

The second thermosetting polymer may be the same formulation as, or different than, the first thermosetting polymer. The identity of the second thermosetting polymer depends on the desired properties of the thermoset polymer that packages the IC device in the second molding operation. There are many commercially available mold compounds containing thermosetting polymers that that those skilled in the art may select for use as the second thermosetting polymer. The second thermosetting polymer in these mold compounds may be a granular material with millimeter sized grains, for example.

The waste thermoset polymer material may be mixed with the second thermosetting polymer using a conventional mechanical mixing technique such as stirring or shaking. The waste thermoset polymer material may be processed to form particles within a desired size range. The size of the particles may be selected so that the particles do not interfere with the general functions of the second plurality of IC devices or with the thermoset form of the second thermosetting polymer. At the average cross-sectional dimension of the particles, an exemplary particle size range is between 50-200 microns. Another exemplary particle size range is between 50-75 microns. At these sizes, the particles function as filler in the mixed thermosetting polymer as will be appreciated by those skilled in the art.

The amount of waste thermoset polymer material used in the mixed thermosetting polymer can vary. For example, the amount may be selected such that the waste thermoset polymer does not substantially diminish the mechanical and thermal properties of the second plurality of IC devices if they had been packaged in the second thermosetting polymer without the waste thermoset polymer. For example, the mixed thermosetting polymer contains less than 20% by weight of the waste thermoset polymer material.

The second plurality of IC devices may be packaged in a second molding operation that is different from the first molding operation. For example, the second molding operation may be a molding operation that produces very little, if any, waste thermoset polymer material when packaging IC devices. One possible, but not the only, example of the second molding operation is compression molding.

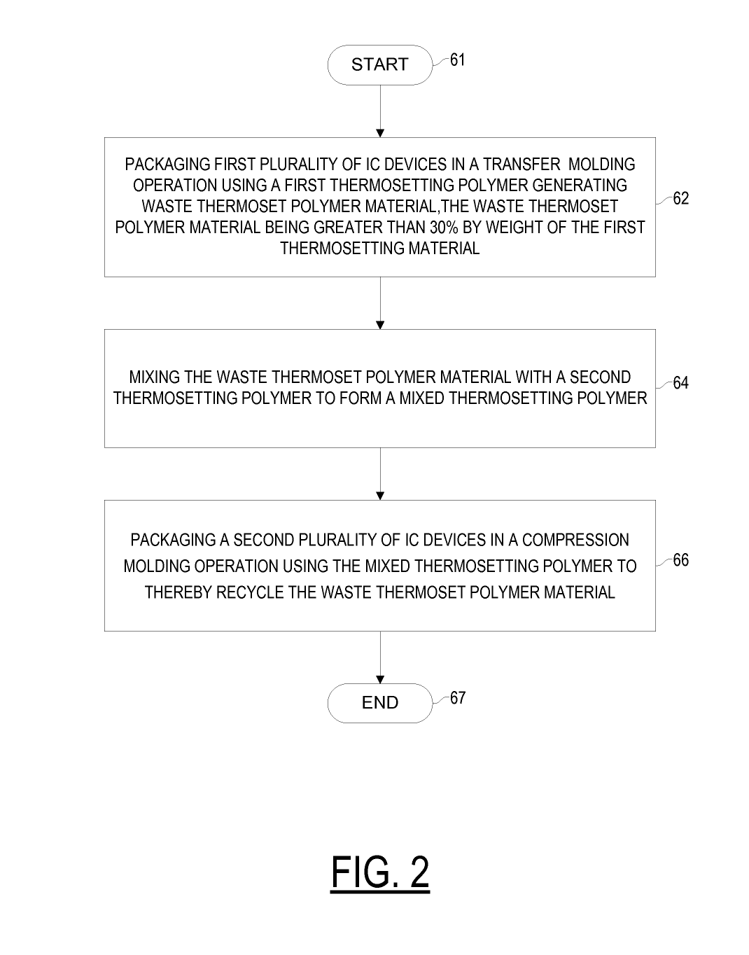

A method of making packaged IC devices, according to a second method aspect is now described with reference to the flowchart in FIG. 2. This method is directed to a particularly advantageous process for recycling waste thermoset polymer produced by transfer molding by using the waste in packaging IC devices by compression molding.

After the start (Block 61), the method includes packaging a first plurality of IC devices in a transfer molding operation using a first thermosetting polymer generating waste thermoset polymer material, with the waste thermoset polymer material being greater than 30% by weight of the first thermosetting material (Block 62). The method also includes mixing the waste thermoset polymer material with a second thermosetting polymer to form a mixed thermosetting polymer (Block 64). Thereafter, the method includes packaging a second plurality of IC devices in a compression molding operation using the mixed thermosetting polymer to thereby recycle the waste thermoset polymer material (Block 66), before stopping at Block 67.

This second method of packaging IC devices is similar to the first method of packaging IC devices described above in connection with FIG. 1. In this second method, however, (a) the first plurality of IC devices are packaged in a transfer molding operation that generates waste thermoset polymer material greater than 30% by weight of the first thermosetting material (Block 62), and (b) the second plurality of IC devices are packaged in a compression molding operation (Block 66).

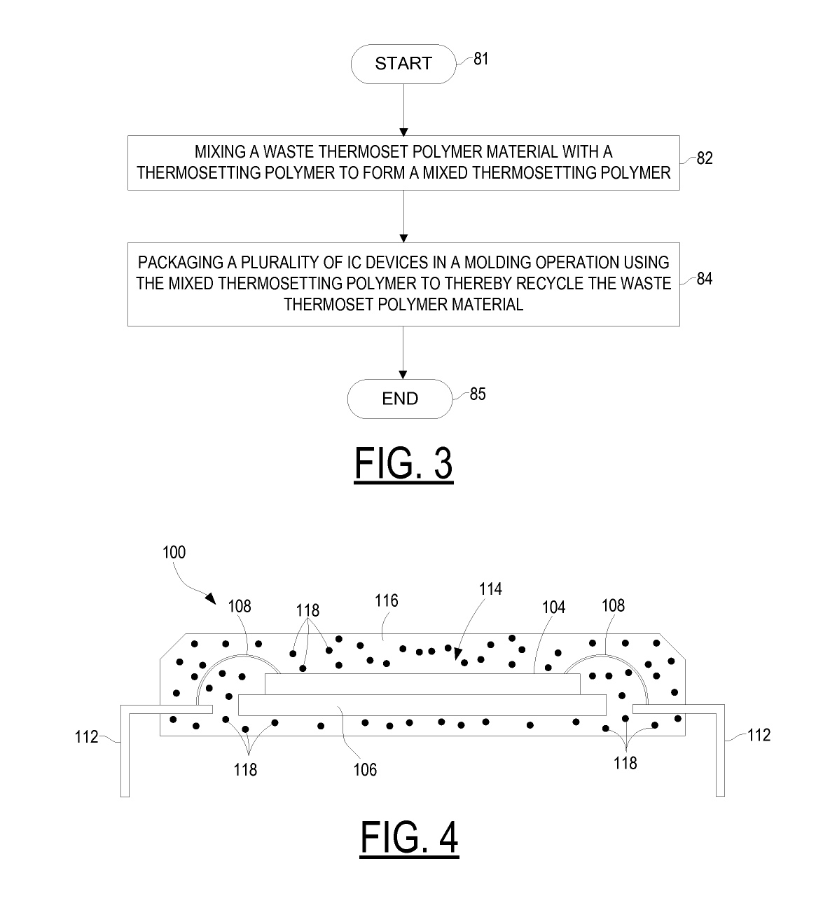

Another method aspect relating to making packaged IC devices is now described with reference to the flowchart in FIG. 3. The method begins at Block 81 and includes mixing a waste thermoset polymer material with a thermosetting polymer to form a mixed thermosetting polymer (Block 82). Next, the method includes packaging a plurality of IC devices in a molding operation using the mixed thermosetting polymer to thereby recycle the waste thermoset polymer material (block 84), before ending at Block 85.

The waste thermoset polymer material in any of these methods or the packaged IC device example described below may also be used as a component in underfill material, which is positioned between the IC chip and lead frame.

Any of the various method aspects described above may be used to make packaged IC devices. An exemplary packaged IC device 100, according to a device aspect is now described with reference to FIG. 4. The packaged IC device 100 illustratively includes an IC device such as semiconductor chip 104. The chip 104 is supported on the die pad 106 of a lead frame or the like. A plurality of bond wires 108 electrically connect the chip 104 to the pins 112 of the lead frame.

The chip 104 is surrounded by or packaged in a body of encapsulating material 114. The encapsulating material 114 includes a thermoset polymer matrix 116 with a plurality of thermoset polymer particles 118 dispersed therein.

The thermoset polymer of the thermoset polymer matrix 116 may be the same formulation as, or different than, the plurality of thermoset polymer particles 118. The thermoset polymer matrix 116 may be formed from a thermosetting polymer used in the packaging of IC devices. Examples of suitable thermosetting polymers useful to form the thermoset polymer matrix are mentioned above.

The thermoset polymer particles 118 may be made of thermoset polymer material that is cured, and thereby thermoset, before being mixed with the thermosetting polymer used to form the thermoset polymer matrix 116 of the encapsulating material 114. Accordingly, the thermoset polymer particles 118 remain intact as particles throughout the curing process of the encapsulating material 114.

Advantageously, the thermoset polymer particles 118 may be obtained from waste thermoset polymer material as described herein. This waste thermoset polymer contains waste material from a thermoset processing operation such as, for example, transfer molding or another molding operation that produces waste thermoset polymer. The identity of the waste thermoset polymer depends on the thermosetting polymer that produced the waste.

The size of the thermoset polymer particles 118 may be selected so that the particles do not interfere with the general functions of the chip 104 or with the thermoset polymer matrix 116 of the encapsulating material 114. At the average cross sectional dimension, a particle size range is between 50-200 microns. At this size, the particles 118 function as filler in the thermosetting polymer matrix 116.

The amount of thermoset polymer particles 118 in the encapsulating material 114 can vary. Preferably, the amount is selected such that the thermoset polymer particles 118 do not substantially diminish the mechanical and thermal properties of the thermoset polymer matrix 116. For example, the encapsulating material 114 contains less than 20% by weight of the thermoset polymer particles 118.

The packaged IC device 100 shown in FIG. 4 is just one example of a packaged IC device that can be made according to the principles described herein. Because the thermoset polymer particles can be incorporated into the encapsulating material used to package many different types of IC devices, the packaged IC device 100 is in no way limited to this particular design.

Various modifications of the embodiments described here can be made without departing from the spirit and scope of the invention as described above and as defined in the appended claims.

What is claimed is:

1. A method of making packaged integrated circuit (IC) devices comprising:
packaging a first plurality of IC devices in a first molding operation using a first thermosetting polymer generating waste thermoset polymer material;
mixing the waste thermoset polymer material with a second thermosetting polymer to form a mixed thermosetting polymer; and
packaging a second plurality of IC devices in a second molding operation, different from the first molding operation, using the mixed thermosetting polymer to thereby recycle the waste thermoset polymer material.

2. The method according to claim 1 wherein the waste thermoset polymer material is greater than 30% by weight of the first thermosetting polymer.

3. The method according to claim 1 wherein the second molding operation does not produce waste mixed thermoset polymer material.

4. The method according to claim 1 wherein the first molding operation comprises transfer molding.

5. The method according to claim 1 wherein the second molding operation comprises compression molding.

6. The method according to claim 1 further comprising processing the waste thermoset polymer material to form particles within a desired size range.

7. The method according to claim 6 wherein a largest cross-sectional dimension of the desired size range is between 50-200 microns.

8. The method according to claim 1 wherein the mixed thermosetting polymer contains less than 20% by weight of the waste thermoset polymer material.

9. The method according to claim 1 wherein the first and second thermosetting polymers have a same formulation.

10. A method of making packaged integrated circuit (IC) devices comprising:
packaging a first plurality of IC devices in a transfer molding operation using a first thermosetting polymer generating waste thermoset polymer material, the waste thermoset polymer material being greater than 30% by weight of the first thermosetting material;
mixing the waste thermoset polymer material with a second thermosetting polymer to form a mixed thermosetting polymer; and
packaging a second plurality of IC devices in a compression molding operation using the mixed thermosetting polymer to thereby recycle the waste thermoset polymer material.

11. The method according to claim 10 wherein the compression molding operation does not produce waste mixed thermoset polymer material.

12. The method according to claim 10 further comprising processing the waste thermoset polymer material to form particles within a range of 50-200 microns at a largest cross-sectional dimension thereof.

13. The method according to claim 10 wherein the mixed thermosetting polymer contains less than 20% by weight of the waste thermoset polymer material.

14. The method according to claim 10 wherein the first and second thermosetting polymers have a same formulation.

15. A method of making packaged integrated circuit (IC) devices comprising:
mixing a waste thermoset polymer material with a thermosetting polymer to form a mixed thermosetting polymer; and
packaging a plurality of IC devices in a molding operation using the mixed thermosetting polymer to thereby recycle the waste thermoset polymer material.

16. The method according to claim 15 wherein the molding operation does not produce waste mixed thermoset polymer material.

17. The method according to claim 15 wherein the molding operation comprises compression molding.

18. The method according to claim 15 further comprising processing the waste thermoset polymer material to form particles within a desired size range.

19. The method according to claim 18 wherein a largest cross-sectional dimension of the desired size range is between 50-200 microns.

20. The method according to claim 15 wherein the mixed thermosetting polymer contains less than 20% by weight of the waste thermoset polymer material.

21. The method according to claim 15 wherein the waste thermoset polymer material and thermosetting polymer have a same formulation.

22. A packaged integrated circuit (IC) device comprising:
an IC device; and
an encapsulating material surrounding said IC device and comprising a thermoset polymer matrix and a plurality of thermoset polymer particles dispersed therein.

23. The packaged IC according to claim 22 wherein the plurality of thermoset polymer particles have a largest cross-sectional dimension in a range between 50-200 microns.

24. The packaged IC according to claim 22 wherein the plurality of thermoset polymer particles comprise less than 20% by weight of the encapsulating material.

25. The packaged IC according to claim 22 wherein the thermoset polymer matrix and plurality of thermoset polymer particles have a same formulation.
